(19) United States
(12) Patent Application Publication
(10) Pub. No.: US 2020/0235114 A1
(43) Pub. Date: Jul. 23, 2020

(54) SEMICONDUCTOR DEVICE AND MANUFACTURING METHOD OF THE SEMICONDUCTOR DEVICE

(71) Applicant: SK hynix Inc., Gyeonggi-do (KR)

(72) Inventor: Young Chan OH, Chungcheongbuk-do (KR)

(21) Appl. No.: 16/597,660

(22) Filed: Oct. 9, 2019

(30) Foreign Application Priority Data
Jan. 18, 2019 (KR) 10-2019-0007103

(51) Int. Cl. H01L 27/11556; H01L 29/788; H01L 29/10

(52) U.S. Cl. CPC H01L 27/11556; H01L 29/1037; H01L 29/788

(57) ABSTRACT

A semiconductor device and a manufacturing method of the semiconductor device are provided. The semiconductor device includes a gate stack comprising interlayer insulating layers and conductive patterns alternately stacked on each other, a channel hole passing through the gate stack, a memory layer formed on a sidewall of the channel hole, a channel layer formed on the memory layer, a core insulating layer filling a central region of the channel hole, and a capping layer formed on the core insulating layer and surrounded by an upper end of the channel layer. The capping layer has a conductive dopant and a growth inhibition impurity.

### CROSS-REFERENCE TO RELATED APPLICATION

The present application claims priority under 35 U.S.C. § 119(a) to Korean patent application number 10-2019-0007103, filed on Jan. 18, 2019, which is incorporated herein by reference in its entirety.

### BACKGROUND

### Field of Invention

Various embodiments of the present disclosure generally relate to a semiconductor device and a manufacturing method of the semiconductor device. More particularly, various embodiments generally relate to a semiconductor device having a polycrystalline film and a manufacturing method of the semiconductor device.

### Description of Related Art

Typically, when a semiconductor device is manufactured, forming a polycrystalline film including a conductive dopant may be employed.

For example, a NAND flash memory device may include a doped polysilicon layer including a conductive dopant. During a process of manufacturing the doped polysilicon layer, voids may be formed in the doped polysilicon layer which may cause the electrical characteristics of the semiconductor device to deteriorate.

### SUMMARY

According to an embodiment of the present invention, a semiconductor device may include a semiconductor substrate including active regions defined by isolation layers, floating gates formed over the active regions, a dielectric layer formed over the semiconductor substrate to cover the floating gates and the isolation layers, and a capping layer formed over the dielectric layer and having a conductive dopant and a growth inhibition impurity.

According to an embodiment of the present invention, a semiconductor device may include a gate stack comprising interlayer insulating layers and conductive patterns alternately stacked on each other, a channel hole passing through the gate stack, a memory layer formed on a sidewall of the channel hole, a channel layer formed on the memory layer, a core insulating layer filling a central region of the channel hole, and a capping layer formed on the core insulating layer and surrounded by an upper end of the channel layer. The capping layer may have a conductive dopant and a growth inhibition impurity.

According to an embodiment of the present invention, a method of manufacturing a semiconductor device may include forming a base structure including a groove and forming a capping layer filling the groove. The capping layer may include a stack of at least one first semiconductor layer and at least one second semiconductor layer, the at least one first semiconductor layer may include a conductive dopant, and the at least one second semiconductor layer may include a growth inhibition impurity.

### BRIEF DESCRIPTION OF THE DRAWINGS

FIGS. 1A and 1B are cross-sectional diagrams illustrating a polycrystalline film according to an embodiment of the present disclosure;

FIG. 2 is a gas supply timing diagram illustrating a method of manufacturing a polycrystalline film according to an embodiment of the present disclosure;

FIG. 3 is a diagram illustrating a polycrystalline film according to an embodiment of the present disclosure;

FIGS. 4 and 5 are a plane view and a cross-sectional diagram, respectively, illustrating a semiconductor device according to an embodiment of the present disclosure;

FIG. 6 is a flowchart of a method of manufacturing the semiconductor device shown in FIGS. 4 and 5;

FIGS. 7A to 7C are perspective views illustrating three-dimensional semiconductor devices according to embodiments of the present disclosure;

FIG. 8 is a cross-sectional diagram illustrating a portion of a pillar for each of the three-dimensional semiconductor devices shown in FIGS. 7A to 7C;

FIG. 9 is a flowchart of a method of manufacturing the pillar shown in FIG. 8;

FIG. 10 is a block diagram illustrating a configuration of a memory system according to an embodiment of the present disclosure; and

FIG. 11 is a block diagram illustrating a configuration of a computing system according to an embodiment of the present disclosure.

### DETAILED DESCRIPTION

Hereinafter, the present invention will be described by way of preferred embodiments of the present disclosure in order for those skilled in the art to which the present disclosure pertains to be able to readily implement the present invention without undue experimentation. However, we note that the present invention may include various other embodiments and various modifications of the described embodiments which do not depart from the scope and technical spirit of the present invention.

While terms such as “first” and “second” may be used to describe various components, such components may not be understood as being limited to the above terms. The above terminologies are used to distinguish one component from the other component, for example, a first component may be referred to as a second component without departing from a scope in accordance with the concept of the present disclosure and similarly, a second component may be referred to as a first component.

It will be understood that when an element is referred to as being “connected” or “coupled” to another element, it may be directly connected or coupled to the other element or intervening elements may also be present. In contrast, when an element is referred to as being “directly connected” or “directly coupled” to another element, no intervening elements are present. It will be understood that when an element is referred to as being “between” two elements, it may be the only element between the two elements, or one or more intervening elements may also be present.

It should be understood that the phrase “at least one of A or B” may mean “only A, only B, or both A and B.”

The terms used in the present application are merely used to describe particular embodiments, and are not intended to limit the present disclosure. Singular forms in the present disclosure are intended to include the plural forms as well, unless the context clearly indicates otherwise. In the present specification, it should be understood that terms “include” or “have” as used herein have the same meaning as the term “comprise” and, therefore, indicate that a feature, a number, a step, an operation, a component, a part or the combination of those described in the specification is present, but do not exclude a possibility of presence or addition of one or more other features, numbers, steps, operations, components, parts or combinations thereof, in advance.

Various embodiments of the present disclosure provide a polycrystalline film, a semiconductor device including the polycrystalline film exhibiting improved electrical characteristics, and a method of manufacturing the semiconductor device.

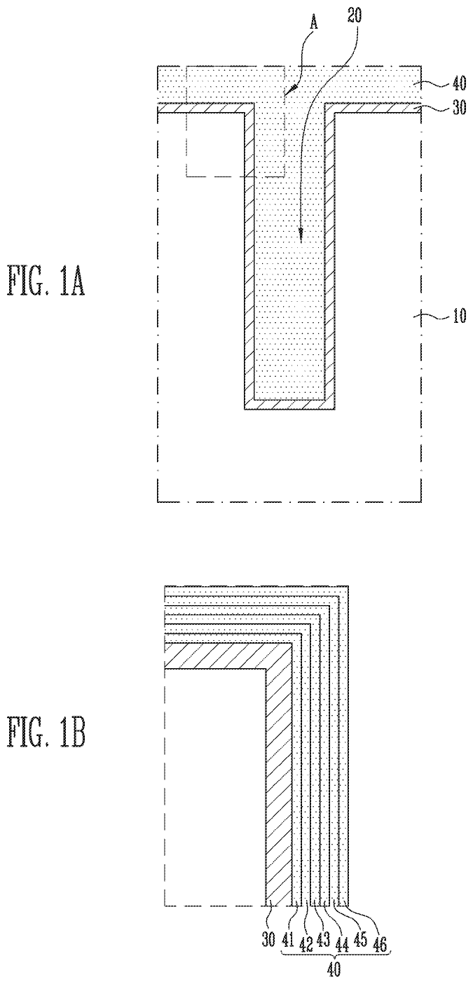

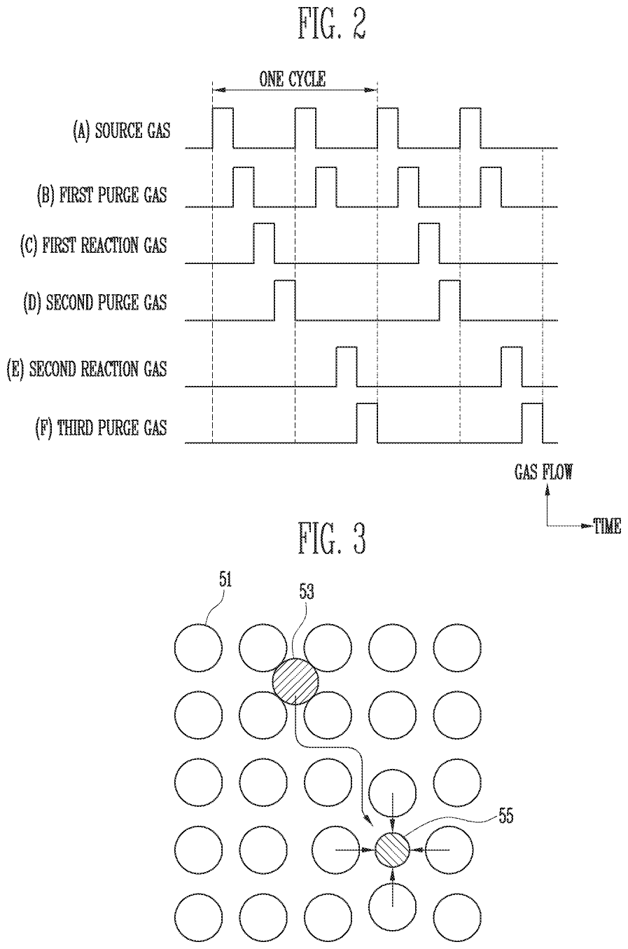

FIGS. 1A and 1B are cross-sectional diagrams illustrating a polycrystalline film 40 according to an embodiment of the present disclosure.

Referring to FIG. 1A, the polycrystalline film 40 according to an embodiment may be formed on a lower structure 10 including a groove 20. The polycrystalline film 40 may fill the groove 20. The polycrystalline film 40 may be formed on a seed layer 30.

The polycrystalline film 40 may serve as a conductive pattern. The polycrystalline film 40 may include a dopant. The polycrystalline film 40 may include a conductive dopant. The polycrystalline film 40 may include an n-type or a p-type conductive dopant. The polycrystalline film 40 may include the conductive dopant in an effective amount so that the polycrystalline film 40 may serve as a conductive pattern. For example, the dopant may be phosphorus, boron fluoride, or arsenic.

The polycrystalline film 40 may include a growth inhibition impurity. The growth inhibition impurity may be used to control a grain size of the polycrystalline film 40. The growth inhibition impurity may be used to reduce a grain size of the polycrystalline film 40. It has been found, that when the groove 20 is filled with the polycrystalline film 40 of which a grain size is reduced due to the presence of the growth inhibition impurity, formation of voids in the groove 20 may be substantially reduced or prevented all together. A mean grain size of the polycrystalline film 40 may be controlled to be less than 100 Å.

Any suitable growth inhibition impurity or impurities may be used in an effective amount for substantially reducing or preventing void formation. For example, suitable growth inhibition impurities may include at least one of carbon, nitrogen, or oxygen.

The polycrystalline film 40 may be formed on the seed layer 30. The seed layer 30 may be a silicon layer. The polycrystalline film 40 may include a plurality of polysilicon layers stacked on the seed layer 30. According to an embodiment of the present invention, the plurality of polysilicon layers may form a stacked structure in which a first silicon layer and a second silicon layer are stacked in an alternating manner over the seed layer 30. The plurality of polysilicon layers may form a stacked structure which includes at least one of first silicon layers and at least one of second silicon layers. The first silicon layers and the second silicon layers are alternately stacked on each other on a surface of the groove 20. FIG. 1B is an enlarged view of a portion A of FIG. 1A. Referring to FIG. 1B, the polysilicon layers forming the polycrystalline film 40 may include first silicon layers 41, 43, and 45, and second silicon layers 42, 44, and 46 that are alternately stacked on each other on the seed layer 30.

Each of the first silicon layers 41, 43, and 45 may include the conductive dopant as described above with reference to FIG. 1A. Each of the second silicon layers 42, 44, and 46 may include the growth inhibition impurity as described above with reference to FIG. 1A. Each of the second silicon layers 42, 44, and 46 including the growth inhibition impurity may have a smaller grain size than each of the first silicon layers 41, 43, and 45. The order in which the first silicon layers 41, 43, and 45 and the second silicon layers 42, 44, and 46 are stacked may be reversed.

The polycrystalline film 40 may be formed using atomic layer deposition. By employing an atomic layer deposition method, step coverage characteristics of the polycrystalline film 40 may be further improved. Accordingly, void formation in the groove 20 may be substantially reduced improved by forming the polycrystalline film 40 having the structure as described above and also by using the atomic layer deposition method.

FIG. 2 is a gas supply timing diagram illustrating a method of manufacturing a polycrystalline film according to an embodiment of the present disclosure. According to a gas supply illustrated in FIG. 2, the first silicon layer and the second silicon layer of the polycrystalline film as described above with reference to FIG. 1B may be formed. A semiconductor substrate for deposition of a polycrystalline film may be disposed in a chamber, and gases for deposition of a polycrystalline film may be supplied into the chamber in accordance with the timings illustrated in FIG. 2.

Referring to FIG. 2, a time period from a start of a process for forming a stacked structure including first pair of the first silicon layer and the second silicon layer to a start of a process for forming a next pair may be defined as one cycle. In other words, one cycle for forming the polycrystalline film may include forming a first pair of the first and second silicon layers.

Referring to FIG. 2, the first silicon layer may be formed by supplying a source gas as illustrated in (A) of FIG. 2 and then supplying a first reaction gas as illustrated in (C) of FIG. 2. After the source gas is supplied and before the first reaction gas is supplied, a first purge gas may be supplied as illustrated in (B) of FIG. 2. After the first reaction gas is supplied and before the source gas is supplied again to form the second silicon layer, a second purge gas may be supplied as illustrated in (D) of FIG. 2.

A silane-based gas, as a gas including silicon, may be used as a source gas. For example, a silane-based gas may include monosilane (MS) (SiH₄), or disilane (DS) (Si₂H₆). A silicon atomic layer may be formed using a source gas.

The first purge gas may be an inert gas and used to remove a remaining source gas.

The first reaction gas may include an n-type or p-type conductive dopant. For example, the first reaction gas may include phosphine (PH₃) including phosphorus. The first silicon layer combined with the conductive dopant may be formed by interaction between the first reaction gas and the silicon atomic layer formed by the source gas.

The second purge gas may be an inert gas and used to remove a reaction residue. The reaction residue may include unreacted first reaction gas.

The second silicon layer may be formed after the second purge gas is suppled as illustrated in (D) of FIG. 2. The second silicon layer may be formed by resupplying the source gas as illustrated in (A) of FIG. 2 and then supplying a second reaction gas as illustrated in (E) of FIG. 2. The first purge gas may be supplied as illustrated in (B) of FIG. 2 after the source gas is supplied and before the second reaction gas is supplied. A third purge gas may be supplied as illustrated in (F) of FIG. 2 after the second reaction gas is supplied and before a next cycle starts.

A silicon atomic layer for the second silicon layer may be formed by resupplying the source gas and a growth inhibition impurity may be combined with the silicon atomic layer for the second silicon layer by the second reaction gas.

The second reaction gas may include the growth inhibition impurity. For example, the second reaction gas may include at least one of carbon, oxygen, or nitrogen. For example, in an embodiment, C₂H₄, C₂H₂ or N₂O may be used as a second reaction gas. The second silicon layer combined with the growth inhibition impurity may be formed by interaction between the second reaction gas and the silicon atomic layer formed on the surface of the first silicon layer by the source gas.

The third purge gas may be an inert gas and used to remove a reaction residue. The reaction residue may include unreacted second reaction gas. The first, second, and third purge gas may employ the same inert gas.

Forming the first silicon layer and forming the second silicon layer may be alternately and repeatedly performed twice or more times by supplying the gases on one cycle basis as described above.

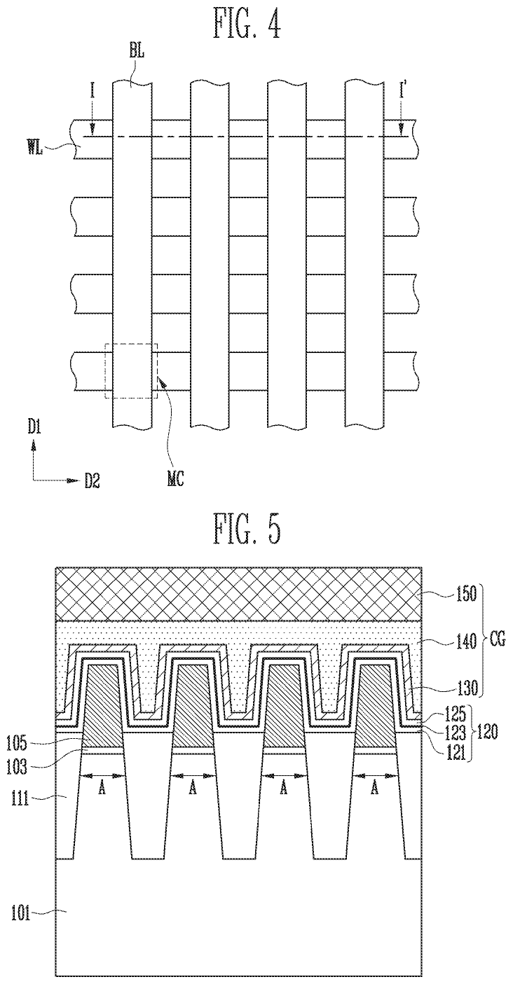

FIG. 3 is a diagram illustrating a polycrystalline film according to an embodiment of the present disclosure. Referring to FIG. 3, the polycrystalline film may include a silicon atom 51, a conductive dopant 53, and a growth inhibition impurity 55. The conductive dopant 53 and the growth inhibition impurity 55 may be combined with the silicon atoms 51 which are positioned in alternating silicon layers of the polycrystalline film 40 as described above. The silicon atom 51 may be combined with the conductive dopant 53, or may be combined with the growth inhibition impurity 55 by the atomic layer deposition as described above with reference to FIG. 2.

The growth inhibition impurity 55 may decrease a grain size of a deposited silicon layer. In addition, the conductive dopant 53 may not easily diffuse within the polycrystalline film layers which have a reduced grain size, and, thus, a concentration of the dopant in the polycrystalline film may be maintained at a target concentration. Accordingly, the electrical characteristics of the polycrystalline film may be maintained.

The polycrystalline film as described above with reference to FIGS. 1A, 1B, and 3 may be used to form a conductive pattern of a semiconductor device or to form a pillar of a three-dimensional semiconductor device.

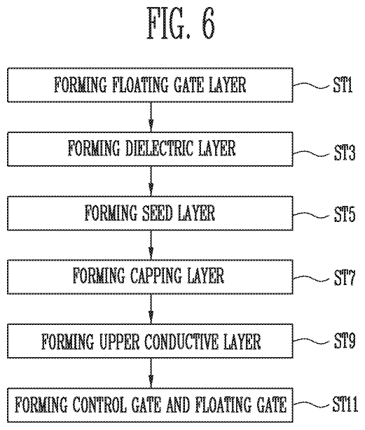

FIGS. 4 and 5 are a plane view and a cross-sectional diagram, respectively, illustrating a semiconductor device according to an embodiment of the present disclosure. For example, FIGS. 4 and 5 illustrate a NAND flash memory device. FIG. 5 is a cross-sectional diagram of a word line WL taken along line I-I′ shown in FIG. 4.

Referring to FIG. 4, a NAND flash memory device may include memory cells MC formed at intersections of the word lines WL and bit lines BL. Each of the bit lines BL may extend in a first direction D1. Each of the word lines WL may extend in a second direction D2. The first direction D1 and the second direction D2 may cross each other when viewed from the top, however, the bit lines and the word line may be positioned at different planes. Referring to FIG. 5, each of the word lines WL illustrated in FIG. 4 may include a control gate CG.

The control gate CG may be formed over a semiconductor substrate 101. Tunnel insulating layers 103, floating gates 105, and a dielectric layer 120 may be disposed between the semiconductor substrate 101 and the control gate CG.

The semiconductor substrate 101 may include active regions A defined by isolation layers 111. The isolation layers 111 and the active regions A may be alternately arranged in the second direction D2 shown in FIG. 4. Each of the isolation layers 111 and the active regions A may extend in the first direction D1 shown in FIG. 4. Each of the active regions A may serve as a channel region. The isolation layers 111 may include an insulating material. The isolation layers 111 may protrude farther towards the control gate CG than the active regions A. In other words, a top surface of each of the isolation layers 111 may be at a level above a top surface of each of the active regions A.

The tunnel insulating layers 103 may be formed on the active regions A of the semiconductor substrate 101, respectively. The tunnel insulating layers 103 may include an oxide layer. The isolation layers 111 may protrude farther towards the control gate CG than the tunnel insulating layers 103.

The floating gates 105 may be formed over respective active regions A, with the respective tunnel insulating layers 103 interposed therebetween. The floating gates 105 may be formed at intersections of the control gate CG and the active regions A. The floating gates 105 may be separated from each other by the isolation layers 111. The floating gates 105 may include at least one of an undoped silicon layer or a doped silicon layer which is doped with a conductive dopant. The floating gates 105 may serve as data storage layers. The floating gates 105 may protrude farther towards the control gate CG than the isolation layers 111. The floating gates 105 may be replaced with charge storage layers that are capable of trapping charges. For example, the charge storage layers may include a silicon nitride layer.

A dielectric layer 120 may cover the isolation layers 111 and the floating gates 105. The dielectric layer 120 may be conformally formed on steps defined by the isolation layers 111 and the floating gates 105. The dielectric layer 120 may leave open a central region of each of a plurality of spaces between the floating gates 105. The dielectric layer 120 may include a first oxide layer 121, a nitride layer 123, and a second oxide layer 125 that are sequentially stacked on each other.

The control gate CG layer may be formed on the dielectric layer 120. The control gate CG layer may include a seed layer 130, a capping layer 140, and an upper conductive layer 150.

The seed layer 130 may be a silicon layer. The seed layer 130 may be formed on the steps defined by the isolation layers 111 and the floating gates 105 on top of the dielectric layer 120. The seed layer 130 may be conformally formed on the dielectric layer 120 and leave open a central region of each of the spaces between the floating gates 105.

The capping layer 140 may include the polycrystalline film described above in FIGS. 1A, 1B, and 3. In other words, the capping layer 140 may include a conductive dopant and a growth inhibition impurity, and include a plurality of polysilicon layers. The polysilicon layers may form a stack including the first and second silicon layers that are described above with reference to FIG. 1B. The capping layer 140 may fill the remaining spaces between the floating gates 105. A grain size of the capping layer 140 may be controlled to be fine in order to substantially reduce or prevent formation of voids in the spaces between the floating gates 105. The grain size may be controlled by controlling the concentration of the growth inhibition impurity employed in the capping layer 140. A mean grain size may be controlled to be less than 100 Å so that the capping layer 140 includes the conductive dopant in an effective amount. As a result, a polysilicon depletion effect of the control gate CG may be reduced,

For example, the capping layer 140 may be formed of a plurality of polysilicon layers including boron and carbon. Boron may be an exemplary example of the conductive dopant and carbon may be an exemplary example of the growth inhibition impurity. A concentration of boron in the capping layer 140 may be 2.0E21 atoms/cm³ or more and a concentration of carbon in the capping layer 140 may be 2.3E21 atoms/cm³.

In order to control the grain size of the capping layer 140, the capping layer 140 may be formed by the atomic layer deposition method described above with reference to FIG. 2. The capping layer 140 including boron and carbon may be formed by using the first reaction gas including boron and the second reaction gas including carbon. When F1 is defined as a flow rate of the first reaction gas including boron and F2 is defined as a flow rate of the second reaction gas including carbon, a flow rate ratio of “F2/(F1+F2)” may be controlled to be 6% or more. In an embodiment, C₂H₄ gas may be supplied as the second reaction gas. In this case, C₂H₄ gas may be supplied at a flow rate of 2.7 cc/sec or more.

The upper conductive layer 150 may be made of any suitable conductive material. The upper conductive layer 150 may be made of a metal layer, a metal containing layer, or a metal silicide layer. Employing a metal layer, a metal containing layer, or a metal silicide layer for the upper conductive layer 150 may decrease the resistance of the control gate CG.

As described above with reference to FIG. 5, the capping layer 140 of the control gate CG which fills the spaces between the floating gates 105 may be formed to be a polycrystalline film having the same structure as the polycrystalline film as described above with reference to FIGS. 1A, 1B, and 3, by the atomic layer deposition method described above with reference to FIG. 2. According to this polycrystalline film, a grain size of the capping layer 140 may be decreased using the growth inhibition impurity included in the capping layer 140. In addition, a phenomenon in which the conductive dopant within the capping layer 140 diffuses outwards may be suppressed using the growth inhibition impurity included in the capping layer 140.

It has been found, that reducing the grain size of the capping layer 140 by controlling the concentration of the growth inhibition impurity in the capping layer, the spaces between the floating gates 105 may be easily buried by the capping layer 140 with a substantial reduction in voids formation inside the spaces or, without any voids formed therein. Moreover, when the phenomenon in which the conductive dopant within the capping layer 140 diffuses outwards is suppressed, a distribution of the conductive dopant within the capping layer 140 may be uniformized.

When the formation of voids and the diffusion of the conductive dopant within the capping layer 140 are minimized, an interference phenomenon between the bit lines BL described above with reference to FIG. 4 may be decreased, and the degree of uniformity of operational characteristics of the memory cells MC may be remarkably increased. For example, a program operation of the memory cells MC of a NAND flash memory device may be controlled by an Incremental Step Pulse Programming (ISPP) method. According to the embodiment of the present disclosure, a distribution of variations in a threshold voltage of the memory cells MC with respect to a step pulse may be decreased by the capping layer 140 according to the embodiment.

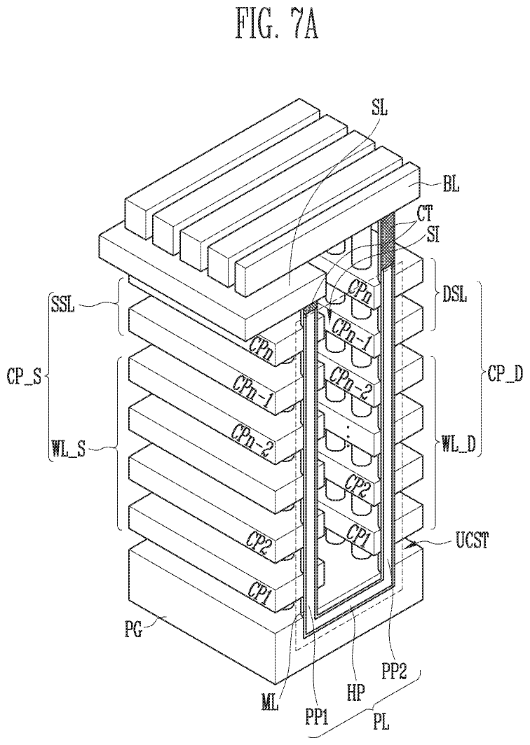

FIG. 6 is a flowchart of a method of manufacturing the semiconductor device illustrated in FIGS. 4 and 5.

Referring to FIG. 6, a floating gate layer may be formed over each of active regions of a semiconductor substrate at step ST1. Forming the floating gate layer may include forming a tunnel insulating layer and a silicon layer on the semiconductor substrate, forming trenches by etching the silicon layer and the tunnel insulating layer, and filling each of the trenches with an isolation layer.

Subsequently, a dielectric layer may be formed to cover the floating gate layer at step ST3. Subsequently, a seed layer may be formed at step ST5.

Subsequently, a capping layer may be formed on the dielectric layer at step ST7. The capping layer may be formed by the atomic layer deposition method described above with reference to FIG. 2.

Subsequently, an upper conductive layer may be formed on the capping layer at step ST9.

Subsequently, an etching process for forming a control gate and a floating gate may be performed at step ST11.

Although an example of the polycrystalline film that may be applied to a two-dimensional NAND flash memory device is illustrated in FIGS. 4 to 6, embodiments of the present disclosure are not limited thereto. For example, the polycrystalline film according to an embodiment of the present disclosure may be applied to a three-dimensional semiconductor device. For example, the three-dimensional semiconductor device may include a plurality of memory cells stacked in a series configuration in a memory cell string extending in a third direction perpendicular to the plane of the first and second directions D1 and D2 shown in FIG. 4.

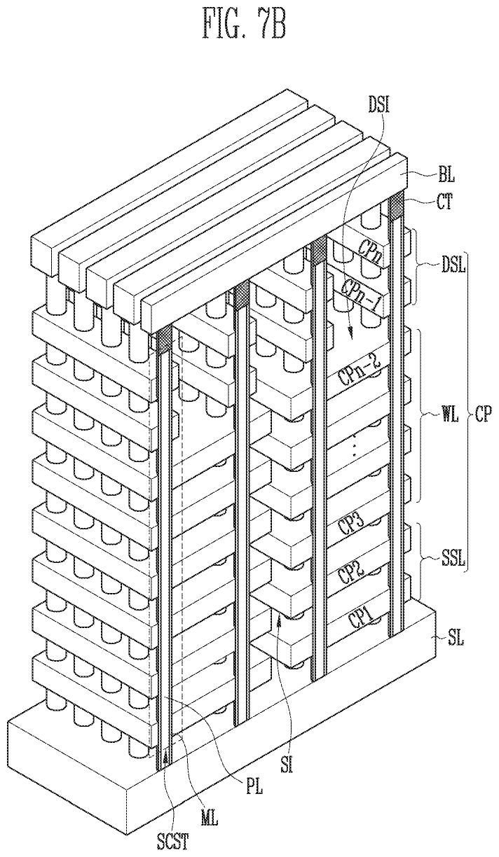

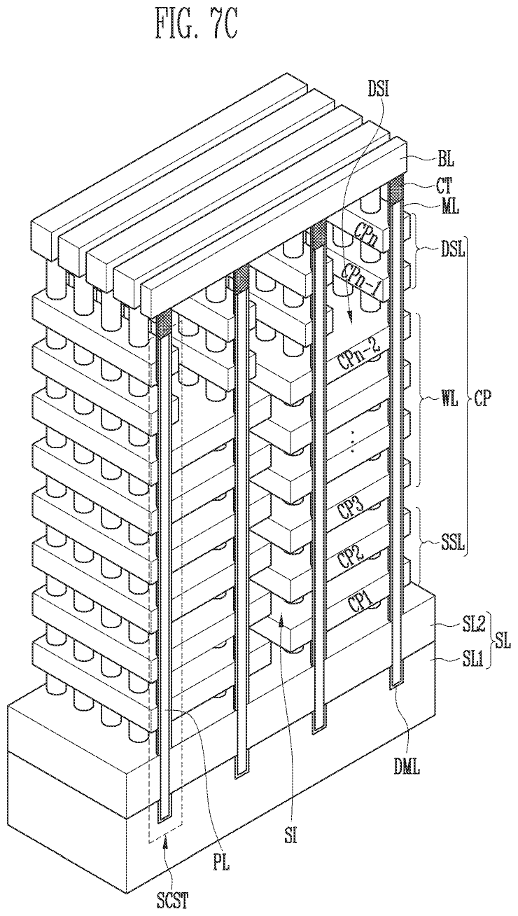

FIGS. 7A to 7C are perspective views illustrating three-dimensional semiconductor devices according to embodiments of the present disclosure.

FIG. 7A shows a perspective view illustrating a semiconductor device having a U-shaped memory string UCST.

Referring to FIG. 7A, the U-shaped memory string UCST may include memory cells, a pipe transistor, and select transistors that are arranged along a pillar PL formed in a U-shape. Cell gates of the memory cells and select gates of the select transistors may be coupled to conductive patterns CP1 to CPn.

The pillar PL may include a horizontal part HP embedded in a pipe gate PG, a first vertical part PP1, and a second vertical part PP2. The first vertical part PP1 and the second vertical part PP2 may extend from the horizontal part HP.

The pillar PL may be electrically coupled between a source line SL and a bit line BL. The bit line BL and the source line SL are disposed in different layers and spaced apart from each other. For example, the source line SL may be disposed below the bit line BL. The source line SL may be electrically coupled to an upper end of the first vertical part PP1. The bit line BL may be electrically coupled to an upper end of the second vertical part PP2. Contact plugs CT may be disposed between the source line SL and the first vertical part PP1 and between the bit line BL and the second vertical part PP2.

The conductive patterns CP1 to CPn may be disposed in n layers spaced apart from each other below the bit line BL and the source line SL. The conductive patterns CP1 to CPn may include source side conductive patterns CP_S and drain side conductive patterns CP_D.

The source side conductive patterns CP_S may enclose the first vertical part PP1 and may be stacked to be spaced apart from each other. The source side conductive patterns CP_S may include source side word lines WL_S and one or more source select lines SSL. The source select lines SSL may be disposed over the source side word lines WL_S. For example, the source select lines SSL may be configured with an nth pattern CPn that is disposed in the uppermost layer of the source side conductive patterns CP_S and an (n−1)th pattern CPn−1 disposed below the nth pattern CPn.

The drain side conductive patterns CP_D may enclose the second vertical part PP2 and be stacked to be spaced apart from each other. The drain side conductive patterns CP_D may include drain side word lines WL_D and one or more drain select lines DSL. The drain select lines DSL may be disposed over the drain side word lines WL_D. The drain select lines DSL may be configured with the nth pattern CPn that is disposed in the uppermost layer of the drain side conductive patterns CP_D and the (n−1)th pattern CPn−1 disposed below the nth pattern CPn.

The source side conductive patterns CP_S and the drain side conductive patterns CP_D may be separated from each other with a slit SI formed therebetween.

The pipe gate PG may be disposed below the source side conductive patterns CP_S and the drain side conductive patterns CP_D and may be formed to surround the horizontal part HP.

A memory layer ML may be formed along an outer surface of the pillar PL. The memory layer ML may include a tunnel insulating layer surrounding the pillar PL, a data storage layer surrounding the tunnel insulating layer, and a blocking insulating layer surrounding the data storage layer.

The source side memory cells may be formed at intersections of the first vertical part PP1 and the source side word lines WL_S. The drain side memory cells may be formed at intersections of the second vertical part PP2 and the drain side word lines WL_D. The source select transistor may be formed at an intersection of the first vertical part PP1 and the source select line SSL. A drain select transistor may be formed at an intersection of the second vertical part PP2 and the drain select line DSL. The pipe transistor may be formed at an intersection of the horizontal part HP and the pipe gate PG. The source select transistor, the source side memory cells, the pipe transistor, the drain side memory cells, and the drain select transistor that are arranged along the single pillar PL may be coupled in series through a channel layer of the pillar PL. The source select transistor, the source side memory cells, the pipe transistor, the drain side memory cells, and the drain select transistor, that are coupled in series along the pillar PL having the U-shape, may define the U-shaped memory string UCST.

The pillar PL may have various shapes in different embodiments, including not only the above-mentioned U-shape but also a W-shape and other shapes. The memory string structure may be changed in various forms depending on the extension structure of the pillar PL.

FIGS. 7B and 7C show perspective views illustrating straight type memory strings SCST.

Referring to FIGS. 7B and 7C, each of the straight type memory strings SCST may include memory cells and select transistors which are stacked along the pillar PL extending in one direction. Cell gates of the memory cells and select gates of the select transistors may be coupled to the conductive patterns CP1 to CPn.

The pillar PL may be electrically coupled to a bit line BL. For this, the pillar PL may be directly coupled to the bit line

BL. Alternatively, the contact plug CT may be formed between the bit line BL and the pillar PL.

A lower end of the pillar PL may be coupled to the source line SL. The source line SL may be formed to have various structures.

As shown in FIG. 7B, the source line SL may come into contact with the bottom of the pillar PL. The source line SL may include a doped polysilicon layer including a first conductivity type impurity. The pillar PL may come into contact with an upper surface of the source line SL and extend toward the bit line BL.

The memory layer ML may surround a sidewall of the pillar PL as shown in FIG. 7B. As described with reference to FIG. 7A, the memory layer ML may include a tunnel insulating layer, a data storage layer, and a blocking insulating layer.

As shown in FIG. 7C, a portion of the lower end of the pillar PL may extend into the source line SL. In other words, the lower end of the pillar PL may pass through a portion of the source line SL.

The source line SL may have a stacked structure including a first source layer SL1 and a second source layer SL2. The first source layer SL1 may surround the lower end of the pillar PL. The second source layer SL2 may be disposed over the first source layer SL1 and be brought into contact with an upper surface of the first source layer SL1 and the sidewall of the pillar PL. The second source layer SL2 may surround the sidewall of the pillar PL. As illustrated, the pillar PL may pass through the second source layer SL2 and terminate within the first source layer SL1.

The memory layer ML may surround a portion of the sidewall of the pillar PL shown in FIG. 7C. As described with reference to FIG. 7A, the memory layer ML may include a tunnel insulating layer, a data storage layer, and a blocking insulating layer. A dummy memory pattern DML may be formed between the pillar PL and the first source layer SL1 and may function as an insulating layer. The dummy memory pattern DML may be formed of the same material layers as that of the memory layer ML. A portion of the pillar PL disposed between the memory layer ML and the dummy memory pattern DML may be brought into direct contact with the second source layer SL2.

Although not shown in FIG. 7C, the source layer may further include a third source layer formed on the second source layer SL2 and surrounding the memory layer ML.

Referring to FIGS. 7B and 7C, the conductive patterns CP1 to CPn may be disposed in n layers spaced apart from each other between the bit line BL and the source line SL. The conductive patterns CP1 to CPn may surround the pillar PL and may be stacked to be spaced apart from each other.

The conductive patterns CP1 to CPn may include one or more source select lines SSL, the word lines WL, and one or more drain select lines DSL. For example, the source select lines SSL may be configured with the first pattern CP1 disposed in the lowermost layer of the conductive patterns CP1 to CPn and the second pattern CP2 disposed over the first pattern CP1. In addition, the drain select lines DSL may be configured with nth pattern CPn disposed in the uppermost layer of the conductive patterns CP1 to CPn and the (n−1)th pattern CPn−1 disposed below the nth pattern CPn. The word lines WL may be disposed between the source select lines SSL and the drain select lines DSL.

The conductive patterns CP1 to CPn may be separated into a plurality of stacked structures by the slit SI. The source select lines SSL or the drain select lines DSL may be separated into units smaller than the word lines WL. Each word line WL may surround the plurality of pillars PL classified into a first group and a second group. In an embodiment, the drain select lines DSL may be classified into a first drain select line, which surrounds pillars of the second group, and a second drain select line, which surrounds the pillars of the second group. The first drain select line may be separated from the second drain select line by a drain separation slit DSI.

According to the configuration described with reference to FIGS. 7B and 7C, memory cells may be formed at intersections of each pillar PL and the word lines WL, a drain select transistor may be formed at an intersection of each pillar PL and the drain select line DSL, and a source select transistor may be formed at an intersection of each pillar PL and the source select line SSL. The source select transistor, the memory cells, and the drain select transistor, which are arranged in a line along each pillar PL, may be coupled in series to each other through the pillar PL and thus define the straight type memory string SCST.

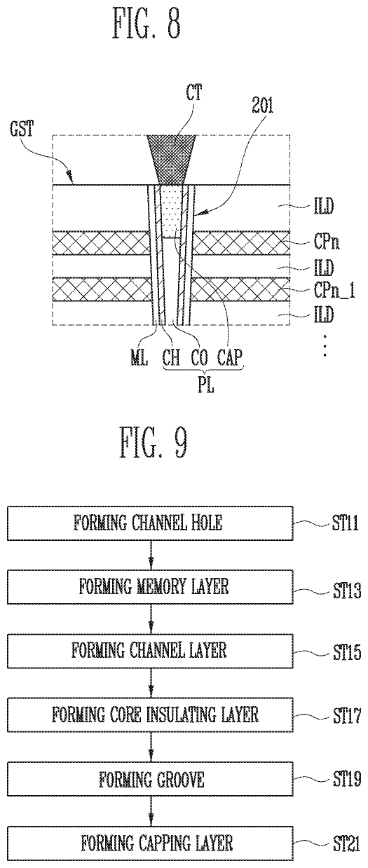

FIG. 8 is a cross-sectional diagram illustrating a portion of the pillar for each of the three-dimensional semiconductor devices shown in FIGS. 7A to 7C.

Referring to FIG. 8, the pillar PL may be disposed in a channel hole 201 passing through a gate stack GST and may be coupled to the corresponding contact plug CT. The gate stack GST may include interlayer insulating layers ILD and the conductive patterns CP1 to CPn shown in FIGS. 7A to 7C, that are alternately stacked on each other.

The memory layer ML described with reference FIGS. 7A to 7C may be formed on a sidewall of the channel hole 201. The pillar PL may include a channel layer CH formed on the memory layer ML, a core insulating layer CO, and a capping layer CAP filling a central region of the channel hole 201.

The channel layer CH may function as a channel. The channel layer CH may be formed of a semiconductor material. In an embodiment, the channel layer CH may be formed of silicon.

The capping layer CAP may be formed on the core insulating layer CO and surrounded by an upper end of the channel layer CH. The capping layer CAP may include the polycrystalline film described above in FIGS. 1A, 1B, and 3. In other words, the capping layer CAP may include a conductive dopant, a growth inhibition impurity, and a plurality of polysilicon layers. The polysilicon layers may form a stack including the first and second silicon layers that are described above with reference to FIG. 1B. The capping layer CAP may fill a top portion of the channel hole 201. A grain size of the capping layer CAP may be controlled to be fine in order to substantially reduce or prevent formation of voids in the channel hole 201. The grain size may be controlled by controlling the concentration of the growth inhibition impurity employed in the capping layer CAP. A mean grain size may be controlled to be less than 100 Å so that the capping layer CAP includes the conductive dopant in an effective amount. The capping layer CAP may be formed by the atomic layer deposition method described above with reference to FIG. 2.

The capping layer CAP which fills the top portion of the channel hole 201 may be formed to be a polycrystalline film having the same structure as the polycrystalline film as described above with reference to FIGS. 1A, 1B, and 3, by the atomic layer deposition method described above with reference to FIG. 2. According to this polycrystalline film, a grain size of the capping layer CAP may be decreased using the growth inhibition impurity included in the capping layer CAP. In addition, a phenomenon in which the conductive dopant within the capping layer CAP diffuses outwards may be suppressed using the growth inhibition impurity included in the capping layer CAP.

FIG. 9 is a flowchart of a method of manufacturing the pillar shown in FIG. 8.

Referring to FIG. 9, a channel hole passing through a stacked structure may be formed at step ST11. The stacked structure may include first material layers and second material layers alternately stacked on each other. For example, the stack structure may be a gate stack including interlayer insulating layers and conductive patterns alternately stacked on each other.

Subsequently, a memory layer may be formed on a surface of the channel hole at step ST13, and then, a channel layer may be formed on the memory layer at step ST15.

Subsequently, a core insulating layer may be formed on the channel layer at step ST17. The core insulating layer may fill a central region of the channel hole.

Subsequently, a groove may be formed at step ST19 by etching a portion of the core insulating layer so as to open a top portion of the channel hole.

Subsequently, a capping layer filling the groove may be formed at step ST21. The capping layer may be formed by the atomic layer deposition method described above with reference to FIG. 2.

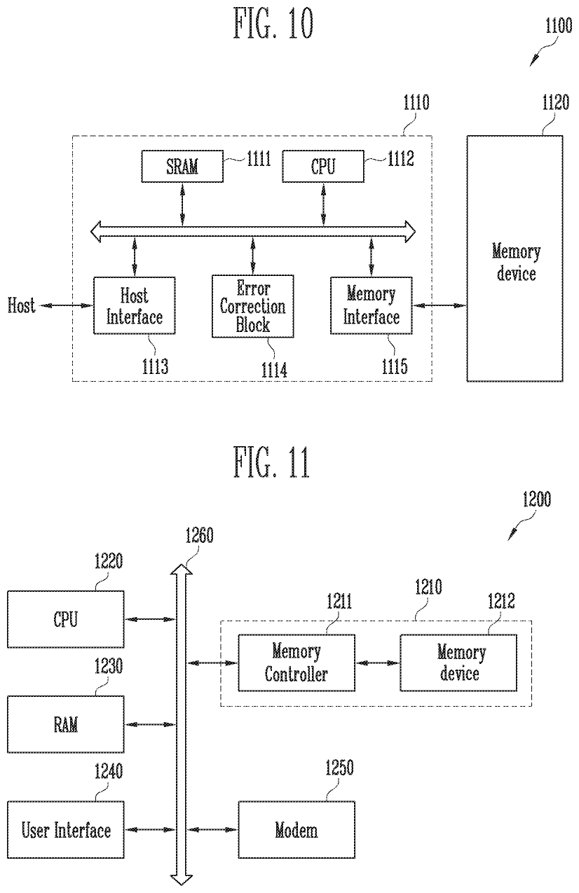

FIG. 10 is a block diagram illustrating a configuration of a memory system 1000 according to an embodiment of the present disclosure.

Referring to FIG. 10, the memory system 1100 according to the illustrated embodiment may include a memory device 1120 and a memory controller 1110.

The memory device 1120 may be a multi-chip package including a plurality of flash memory chips. The memory device 1120 may include the polycrystalline film described above with reference to FIGS. 1A and 1B, include the NAND flash memory device described above with reference to FIGS. 4 and 5, or include at least one of the three-dimension semiconductor devices described above with reference to FIGS. 7A to 7C, and 8.

The memory controller 1110 may be configured to control the memory device 1120 and include Static Random Access Memory (SRAM) 1111, a central processing unit (CPU) 1112, a host interface 1113, an error correction block 1114, and a memory interface 1115. The SRAM 1111 may serve as an operation memory of the CPU 1112, the CPU 1112 may perform a control operation for data exchange of the memory controller 1110, and the host interface 1113 may include a data exchange protocol of a host accessing the memory system 1100. In addition, the error correction block 1114 may detect and correct errors included in the data read from the memory device 1120, and the memory interface 1115 may perform interfacing with the memory device 1120. In addition, the memory controller 1110 may further include Read Only Memory (ROM) for storing code data for interfacing with the host.

The memory system 1100 having the above-described configuration may be a Solid State Drive (SSD) or a memory card in which the memory device 1120 and the memory controller 1110 are combined. For example, when the memory system 1100 is an SSD, the memory controller 1110 may communicate with an external device (e.g., a host) through one of the interface protocols including a Universal Serial Bus (USB), a MultiMedia Card (MMC), Peripheral Component Interconnection-Express (PCI-E), Serial Advanced Technology Attachment (SATA), Parallel Advanced Technology Attachment (PATA), a Small Computer Small Interface (SCSI), an Enhanced Small Disk Interface (ESDI), and Integrated Drive Electronics (IDE).

FIG. 11 is a block diagram illustrating a configuration of a computing system 1200 according to an embodiment of the present disclosure.

Referring to FIG. 11, the computing system 1200 according to the embodiment may include a CPU 1220, Random Access Memory (RAM) 1230, a user interface 1240, a modem 1250, and a memory system 1210 that are electrically coupled to a system bus 1260. In addition, when the computing system 1200 is a mobile device, a battery for supplying an operating voltage to the computing system 1200, an application chipset, a camera image processor (CIS), a mobile DRAM, and the like may be further included.

According to embodiments of the present disclosure, a polycrystalline film may include a growth inhibition impurity as well as a conductive dopant, thereby a grain size of a polycrystalline film may be decreased. According to embodiments, even when the polycrystalline film fills a space having a high aspect ratio, a phenomenon in which a void is generated in the polycrystalline film may be decreased. As a result, according to embodiments of the present disclosure, electrical characteristics of the polycrystalline film and the semiconductor device employing the polycrystalline film may be improved.

The above-discussed embodiments aim to help those with ordinary knowledge in this art more clearly understand the present disclosure rather than aiming to limit the bounds of the present disclosure. It should be understood that many variations and modifications of the basic inventive concept described herein will still fall within the spirit and scope of the present disclosure as defined in the accompanying claims and equivalents thereof.

So far as not being differently defined, all terms used herein including technical or scientific terminologies have meanings that they are commonly understood by those skilled in the art to which the present disclosure pertains. So far as not being clearly defined in this application, terms should not be understood in an ideally or excessively formal way.

What is claimed is:

1. A semiconductor device comprising:
a semiconductor substrate including active regions defined by isolation layers;
floating gates formed over the active regions;
a dielectric layer formed over the semiconductor substrate to cover the floating gates and the isolation layers; and
a control gate formed over the dielectric layer, the control gate including a capping layer having a conductive dopant and a growth inhibition impurity.

2. The semiconductor device of claim 1, wherein the capping layer fills a space between the floating gates adjacent to each other in a direction crossing the isolation layers, and
wherein the control gate further includes an upper conductive layer formed on the capping layer.

3. The semiconductor device of claim 1, wherein the capping layer includes at least one of first silicon layers each having the conductive dopant and at least one of second silicon layers each having the growth inhibition impurity.

4. The semiconductor device of claim 3, wherein the capping layer comprises a stack formed over the dielectric layer, and
wherein the stack includes a plurality of the first silicon layers and the second silicon layers alternately stacked on each other over the dielectric layer.

5. The semiconductor device of claim 8, further comprising a seed layer formed between the capping layer and the dielectric layer.

6. The semiconductor device of claim 1, wherein the growth inhibition impurity includes at least one of carbon, nitrogen, or oxygen.

7. The semiconductor device of claim 1, wherein the conductive dopant includes an n-type or a p-type dopant.

8. The semiconductor device of claim 1, wherein the capping layer comprises a polycrystalline film having a grain size less than 100 Å.

9. A semiconductor device comprising:
a gate stack comprising interlayer insulating layers and conductive patterns alternately stacked on each other;
a channel hole passing through the gate stack;
a memory layer formed on a sidewall of the channel hole;
a channel layer formed on the memory layer;
a core insulating layer filling a central region of the channel hole; and
a capping layer formed on the core insulating layer and surrounded by an upper end of the channel layer,
wherein the capping layer has a conductive dopant and a growth inhibition impurity.

10. The semiconductor device of claim 9, wherein the capping layer fills a top portion of the channel hole.

11. The semiconductor device of claim 9, wherein the capping layer includes at least one of first silicon layers each having the conductive dopant and at least one of second silicon layers each having the growth inhibition impurity.

12. The semiconductor device of claim 11, wherein the capping layer comprises a stack includes the plurality of the first silicon layers and the second silicon layers alternately stacked on each other.

13. The semiconductor device of claim 9, wherein the growth inhibition impurity includes at least one of carbon, nitrogen, or oxygen.

14. The semiconductor device of claim 9, wherein the conductive dopant includes an n-type or a p-type dopant.

15. The semiconductor device of claim 9, wherein the capping layer comprises a polycrystalline film having a grain size less than 100 Å.
